(19) United States
(12) Patent Application Publication
(10) Pub. No.: US 2013/0078768 A1
(43) Pub. Date: Mar. 28, 2013

(54) NEST MECHANISM WITH RECESSED WALL SEGMENTS

(71) Applicants: RANDY HSU, TAIPEI (TW); CLIFF HO, TAIPEI (TW)

(72) Inventors: RANDY HSU, TAIPEI (TW); CLIFF HO, TAIPEI (TW)

(73) Assignee: TEXAS INSTRUMENTS INCORPORATED, Dallas, TX (US)

(21) Appl. No.: 13/247,463

(22) Filed: Sep. 28, 2011

(51) Int. Cl. H01L 21/50; B23Q 3/00

(52) U.S. Cl. 438/113; 269/305; 257/E21.499

(57) ABSTRACT

A nest mechanism includes a 2-dimensional grid of support positions for supporting singulated electronic units. The support positions each include an inner opening and an outer horizontal base around the inner opening having a support surface that supports units thereon. A segmented wall arrangement is on the outer horizontal base located beyond an area of the unit for preventing movement of the unit while on the support surface. The segmented wall arrangement includes (i) a plurality of raised wall segments that extend to a first height above the support surface, and (ii) at least one recessed segment between the plurality of raised wall segments that has a height less than the first height. The recessed segment(s) help liquid-based washing processes to remove residue material generated by a sawing process that can become stuck under the units while in the nest mechanism awaiting transfer.

### FIELD

Disclosed embodiments relate to nest mechanisms involved in the dicing separation of electronic packages formed on a common carrier.

### BACKGROUND

During assembly and packaging of electronic devices, multiple semiconductor dice are generally placed onto a single carrier in array form (e.g., leadframe or organic substrate panel or sheet) and processed in bulk for increasing throughput. After electrical connections are made between the dice and the carrier, such as by wirebonding, the dice, together with the electrical connections in a typical assembly flow may be encapsulated with a molding compound for providing protection from the external environment. Thereafter, the resulting packages that encapsulate the dice are cut in a singulation step to separate them from one another to form singulated packaged electronic units (“units”).

The separation of the units is generally accomplished by sawing with a blade. After sawing, the units are further processed, for example by washing, drying, inspection and finally offloading, such as by pick and place.

One sawing approach is a nesting jig saw approach. A conventional nest mechanism comprises a 2-dimensional grid including vertical nest side walls that completely surround openings having outer horizontal surfaces which define respective grid positions. The nest mechanism is placed onto a saw jig before sawing, and a substrate to be sawn is supported on the nest side walls. The substrate is then sawn to form the units. After sawing, the units may sit on the horizontal surfaces that are bounded by nest side walls. Washing after sawing can remove some of the residue material (such as whiskers from the substrate and/or the molding compound) generated by the sawing process. However, some residue material may remain on the horizontal surfaces or on the nest side walls. Such residue material when under the units can cause the units to be tilted (and thus not be flat) while sitting in the nest mechanism, which can cause unloading processes from the nest mechanism to encounter transfer problems (e.g., pick and place failures).

### SUMMARY

Disclosed embodiments include nest mechanisms for semiconductor assembly that alters the shape of the nest side walls from conventional continuous (360 degrees; completely surrounding) walls having constant height side walls to a segmented wall arrangement that includes one or more recessed segments between raised wall segments. The recessed segment(s), which in one embodiment comprises gap(s), allows a fluid flow during washing operations to pass there through. Disclosed segmented wall arrangements can reduce the probability of residual material from being deposited near the nest walls, and can increase the efficiency of residual material removal by the washing step, which each help reduce the concentration of residual material stuck under the singulated packaged electronic units (“units”) while in the nest. Reducing the incidence of residual material stuck under the units while awaiting transfer from the nest mechanism reduces the incidence of transfer problems from the nest, such as pick and place failures.

Disclosed nest mechanisms include a 2-dimensional grid of support positions. The support positions each include an inner opening and an outer horizontal base around the inner opening having a support surface for supporting a unit thereon. A segmented wall arrangement is on the outer horizontal base located beyond an area of the unit for preventing movement of the unit while on the support surface. The segmented wall arrangement includes (i) a plurality of raised wall segments that extend to a first height above the support surface, and (ii) at least one recessed segment between the plurality of raised wall segments that has a height less than the first height. The recessed segment(s) help liquid-based washing processes to remove residue material generated by a sawing process that can become stuck under the units while in the nest mechanism awaiting transfer.

### BRIEF DESCRIPTION OF THE DRAWINGS

FIG. 1A is a top view depiction of an example support position within an example nest mechanism having a segmented wall arrangement, where the recessed segments between raised wall segments are gaps, according to an example embodiment.

FIG. 1B is a top view depiction of another example support position within an example nest mechanism having a segmented wall arrangement, where the recessed segments between raised wall segments extend in height above the support surface, according to an example embodiment.

FIG. 2 is a top view depiction of an example nest mechanism having a segmented wall arrangement including raised wall segments and recessed wall segments between the raised wall segments, according to an example embodiment.

FIG. 3 is a top view of a portion of an example nest mechanism having a segmented wall arrangement, showing units sitting on support surfaces having raised wall segments that partially surround the units, according to an example embodiment.

FIG. 4A (prior art) and 4B are expanded perspective depictions of a portion of a conventional nest mechanism and the nest mechanism shown in FIG. 1A, respectively, with the units shown removed to allow viewing the liquid flow direction(s) depicted during washing of the units.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

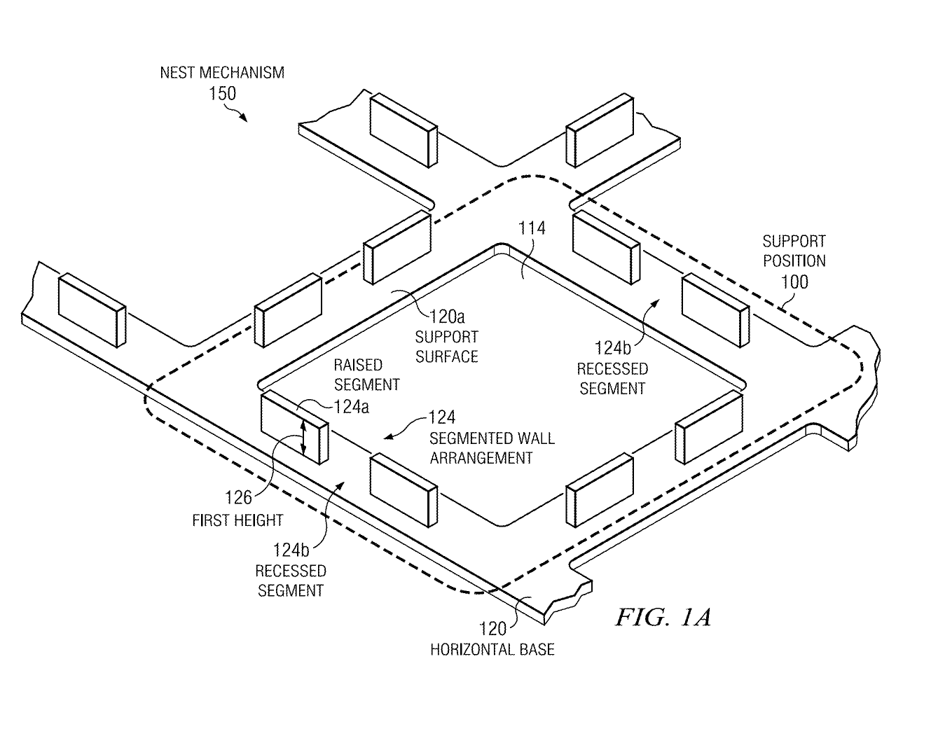

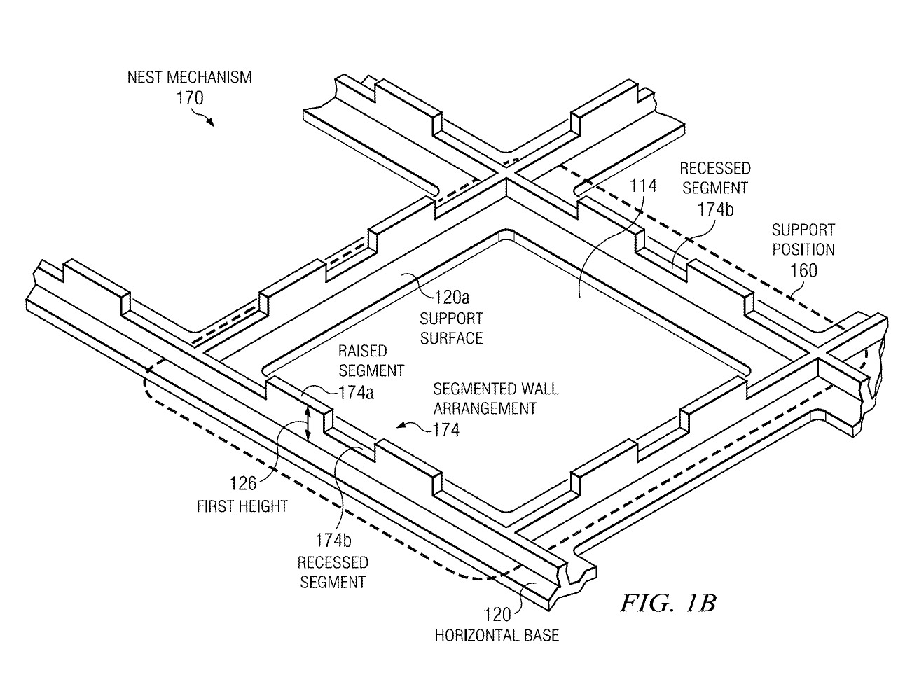

FIG. 1A is an expanded perspective depiction of an example support position 100 within an example nest mechanism 150 having segmented wall arrangements, according to an example embodiment. Nest mechanism 150 comprises a 2-dimensional grid of support positions 100. Each support position 100 includes an inner opening 114 surrounded by an outer horizontal base 120 around the inner opening. The horizontal base 120 includes a support surface 120(a) for supporting a unit thereon. Units can comprise molded leadframe-based units, molded substrate-based units such as organic or ceramic substrates that can include ball grid arrays (BGAs), or non-molded units such as Wafer Level Chip Scale Packages (WL-CSPs).

A disclosed segmented wall arrangement 124 is on the outer horizontal base 120 positioned beyond an area of the units. Segmented wall arrangement 124 includes raised wall segments 124a that partially surrounds the units, and recessed segments 124b between the raised wall segments 124a. Although segmented wall arrangement 124 defines a rectangular area to match rectangular units, disclosed segmented wall arrangement can be provided in a variety of shapes to match the shape of the units, such as octagon-shaped, or circular-shaped.

As shown in FIG. 1A, there are two raised wall segments 124a per side of each support position 100. However, disclosed nest mechanisms can include generally any number of raised wall segments 124a, such as 3, 4, 5, or 10 per side for shapes that include sides. Raised wall segments 124a are shown extending to a first height 126 that is above the support surface 120a. The recessed segments 124b are shown having a height that is less than less than the first height 126. As shown in FIG. 1A, the recessed segments 124b are gaps between the raised wall segments 124a.

FIG. 1B is an expanded perspective depiction of an example support position 160 within an example nest mechanism 170 having segmented wall arrangements, according to an example embodiment. As shown, segmented wall arrangement 174 comprises recessed segments 174b between raised wall segments 174a, where the recessed segments 174b extend above the support surface 120a, such a height that is 5 to 50% of the first height 126.

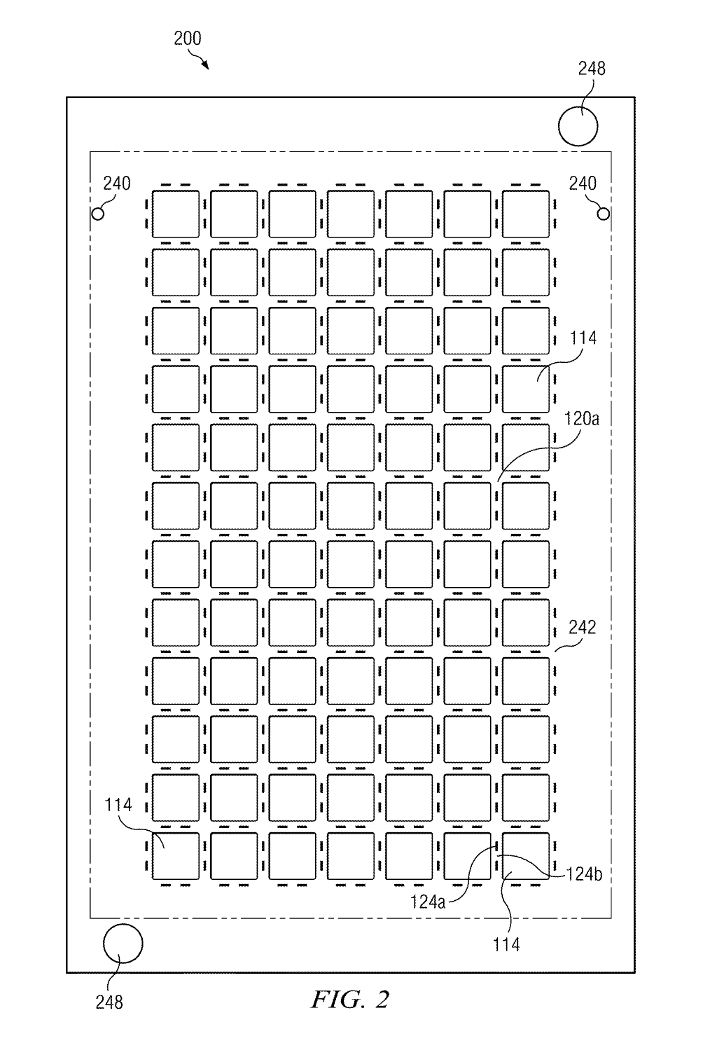

FIG. 2 is a top view depiction of an example nest mechanism 200 having support positions 100 including the segmented wall arrangement 124 shown in FIG. 1A including raised wall segments 124a and recessed segments 124b between the raised wall segments, according to an example embodiment. As described above, the raised wall segments 124a of nest mechanism 200 partially surround the units to reduce the movement of the units while positioned within nest mechanism 200. Nest mechanism 200 may comprise a variety of different materials, such as stainless steel in one embodiment, or a plastic in another embodiment. Alignment pins 240 on nest mechanism 200 can be used to engage locator holes on a substrate in order to position the substrate with respect to nest mechanism 200.

The topside (active/circuit side) or the bottomside of the substrate may be placed “face down” on nest mechanism 200. For example, a bottomside of a substrate having a BGA may be placed onto nest mechanism 200. As shown, while grid arrangement 242 defines eighty four openings 214, the number of openings 214 may be widely varied.

Each support position 100 effectively “holds” one unit. Nest mechanism 200 may be mounted against a vacuum chuck that is a part of a dicing saw assembly. The vacuum chuck generates a vacuum which engages the substrate mounted on nest mechanism 200 through inner openings 114. Pilot locator holes 248 are shown for mounting nest mechanism 200 against a vacuum chuck, where pilot locator holes 248 are arranged to fit over dowels, or similar structures, on the vacuum chuck.

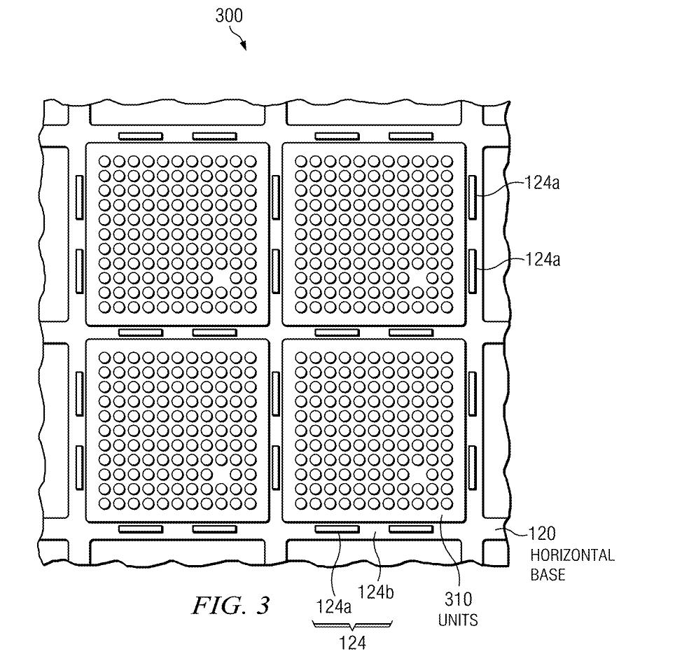

FIG. 3 is a top depiction derived from an actual image of a portion of an example nest mechanism 300 having support positions 100 shown in FIG. 1A including disclosed segmented wall arrangements 124, according to an example embodiment. The units 310 are shown having BGAs that face up, and the units sit on support surfaces having the raised wall segments 124a that partially surround the units 310.

As disclosed above, the recessed segments 124b help liquid-based washing processes remove residue material generated by a sawing process that can become stuck under the units while in the nest mechanism awaiting transfer. When residue material is under the units, the units will be lifted up on one edge and become tilted once touching the residue material, resulting in transfer failures from transfer processes from the nest mechanism, such as by pick and place. Disclosed nest mechanisms having segmented wall arrangements significantly lower failure rates as compared to conventional nest arrangements due to a lower probability of residual material deposited during sawing near the walls of segmented wall arrangement and improved efficiency of residual material removal by the washing step, which each help reduce the concentration of residual material stuck under the units 310 following washing.

Assembly sequences that includes washing to remove particles from a nest mechanism can benefit from disclosed nest mechanisms, such as the sequence of sawing, then washing the nest having units “held” therein in the respective support positions by flowing a liquid such as water through the nest openings, drying, then removing units from the nest mechanism. A typical removal process is pick and place. Disclosed embodiments include a method of semiconductor device assembly including sawing and washing using a disclosed nest mechanism. The method comprises sawing a substrate (e.g., sheet or panel) including a plurality of semiconductor die to form a plurality of singulated packaged electronic units, wherein the sawing generates residue material. The plurality of singulated packaged electronic units are received in respective support positions of a disclosed nest mechanism. A nest cover is positioned over the nest mechanism that has a spacing relative to the nest mechanism. A washing step removes residue material in the nest mechanism by directing a flow of liquid through the inner openings of the nest mechanism. The flow of liquid includes flow paths over the recessed segments, which improves the efficiency of residual material removal by the washing step, which helps reduce the concentration of residual material stuck under the units following washing. Units can then be dried, and transferred from the nest mechanism, such as by pick and place.

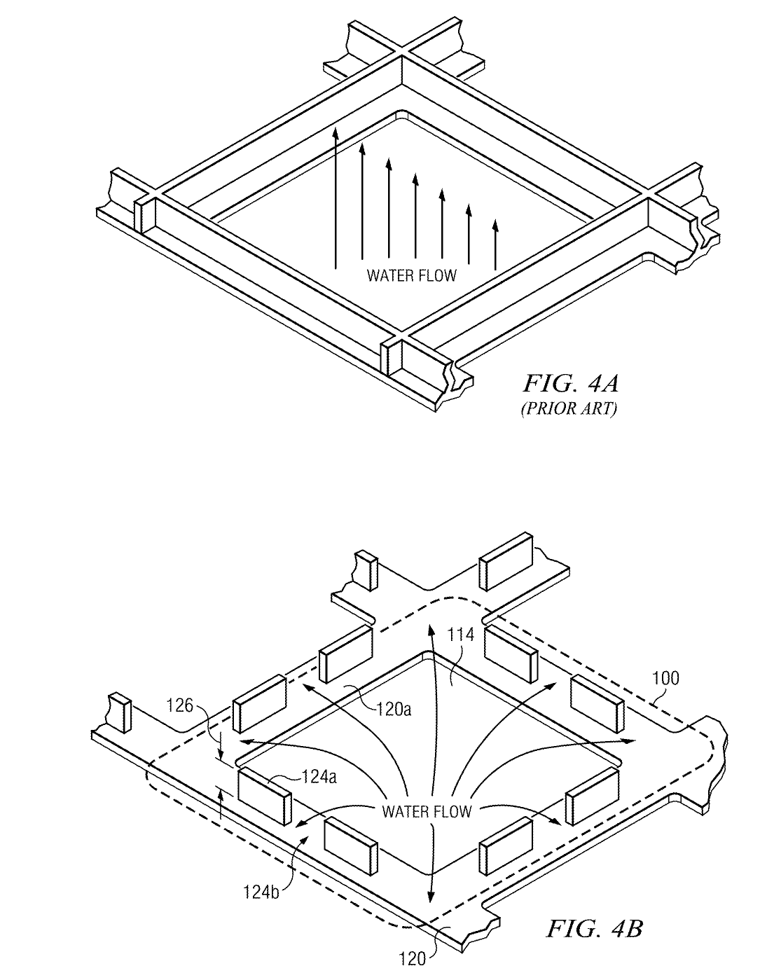

FIG. 4A (prior art) and 4B are expanded perspective depictions of a portion of a conventional nest mechanism and the nest mechanism shown in FIG. 1A, respectively, during washing after sawing, with the units shown removed to allow viewing the liquid flow direction(s) during washing of the units. FIG. 4A depicts single direction liquid flow during washing for the conventional nest mechanism which disclosed embodiments recognize as having low efficiency for removing residue material, while FIG. 4B depicts multi-direction liquid flow during washing using the nest mechanism 150 shown in FIG. 1A having support positions 100 including the segmented wall arrangement including raised wall segments 124a and recessed segments 124b between the raised wall segments.

Disclosed embodiments can be integrated into a variety of assembly flows to form a variety of different integrated circuit (IC)-based devices and related products. The IC assembly can comprise single IC die or multiple IC die, such as PoP configurations comprising a plurality of stacked IC die. A variety of package substrates may be used. The IC die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the IC die can be formed from a variety of processes including bipolar, CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

We claim:

1. A nest mechanism, comprising:
a 2-dimensional grid of support positions, said support positions each including:
an inner opening and an outer horizontal base around said inner opening having a support surface for supporting a singulated electronic unit thereon, and
a segmented wall arrangement on said outer horizontal base located beyond an area of said singulated electronic unit for preventing movement of said singulated electronic unit while on said support surface,
wherein said segmented wall arrangement includes:
(i) a plurality of raised wall segments that extend to a first height above said support surface, and
(ii) at least one recessed segment between said plurality of raised wall segments that has a height less than said first height.

2. The nest mechanism of claim 1, wherein said recessed segment is a gap between said raised wall segments.

3. The nest mechanism of claim 1, wherein said recessed segment extends in said height above said support surface.

4. The nest mechanism of claim 2, wherein said support positions are rectangularly shaped including first, second, third and fourth sides, and wherein each of said first, second, third and fourth sides include said gap.

5. The nest mechanism of claim 1, wherein said nest mechanism comprises steel.

6. A nest mechanism, comprising:
a 2-dimensional grid of support positions, said support positions each including:
an inner opening and an outer horizontal base around said inner opening having a support surface for supporting a singulated electronic unit thereon, and
a segmented wall arrangement on said outer horizontal base located beyond an area of said singulated electronic unit for preventing movement of said singulated electronic unit while on said support surface,
wherein said segmented wall arrangement includes:
(i) a plurality of raised wall segments that extend to a first height above said support surface, and
(ii) at least one recessed segment comprising a gap between said plurality of raised wall segments,
wherein said support positions are rectangularly shaped including first, second, third and fourth sides, and wherein each of said first, second, third and fourth sides include said gap.

7. A method of semiconductor device assembly, comprising:
sawing a substrate including a plurality of semiconductor die to form a plurality of singulated packaged electronic units, wherein said sawing generates residue material;
receiving said plurality of singulated packaged electronic units in respective support positions of a nest mechanism, said support positions each including an inner opening and an outer horizontal base around said inner opening having a support surface for supporting a singulated electronic unit thereon, and a segmented wall arrangement on said outer horizontal base located beyond an area of said unit for preventing movement of said unit while on said support surface, wherein said segmented wall arrangement includes: (i) a plurality of raised wall segments that extend to a first height above said support surface, and (ii) at least one recessed segment between said plurality of raised wall segments that has a height less than said first height,
positioning a nest cover over said nest mechanism that has a spacing relative to said nest mechanism, and
washing to remove said residue material in said nest mechanism by directing a flow of liquid through said inner openings, wherein said flow of liquid includes flow paths over said recessed segments.

8. The method of claim 7, wherein said recessed segment is a gap between said raised wall segments.

9. The method of claim 7, wherein said recessed segment extends in height above said support surface.

10. The method of claim 8, wherein said support positions are rectangularly shaped including first, second, third and fourth sides, and wherein each of said first, second, third and fourth sides include said gap.

11. The method of claim 7, wherein said units comprise molded packages.

12. The method of claim 7, wherein said units comprise Wafer Level Chip Scale Packages (WL-CSPs).
